(19) United States
(12) Patent Application Publication
(10) Pub. No.: US 2007/0279874 A1
(43) Pub. Date: Dec. 6, 2007

(54) PC card kit and PC card

(75) Inventors: Hao Gu, Kunshan (CN); Qi-Sheng Zheng, Kunshan (CN); Zhi-Quan Mou, Kunshan (CN); Kai-Gang Yu, Kunshan (CN)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 11/809,339

(22) Filed: May 31, 2007

(30) Foreign Application Priority Data
May 31, 2006 (CN) 200620073581.2

(51) Int. Cl. H05K 1/14

(52) U.S. Cl. 361/737

(57) ABSTRACT

A PC card includes a pair of shells, a printed circuit board interposed between the shells, an insulative frame supporting the printed circuit board, a top cover, and a bottom cover engaging with the top cover. The insulative frame includes a pair of longitudinal rails and the top cover is connected with rear ends of the rails. An enforcement mechanism is arranged on front ends of the top cover and the bottom cover for fastening the bottom cover to the top cover. The enforcement mechanism includes a protrusion and a recess mating with each other.

### BACKGROUND OF THE INVENTION

1. Field of the Invention

The present invention is related to a PC card kit of a PC card which is used in computers and other electronic equipments.

2. Description of Related Art

PC cards are widely used in desktop computers, facsimile machines, notebook computers and other electronic equipments. Each of the PC cards generally comprises a printed circuit board (PCB), at least an PC card mounted to the PCB and a PC card kit enclosing the PCB and the PC card. With the development of the technology, the circuitry of the PCB of the PC card become more and more complex and is easily damaged in use. Further, the PC card is highly desired to provide reliable data in higher transferring speeds, so it is necessary to design a PC card kit that encloses and protects the PCB more reliably.

U.S. Pat. No. 6,849,801 discloses a PC card comprising a PCB, a connector mounted on one end of the PCB, and a PC card kit surrounding the PCB and the connector. The PC card kit comprises a frame which has a pair of longitudinal rails, a transverse bar interconnecting the rails and a top cover integrally formed with the transverse bar. The opposite sides of the PCB are covered by two metal shells of stainless steel. A bottom cover of a synthetic resin material is secured to the bottom shell and the frame. The rear end of the PCB was shielded by the bottom cover and the top cover. Since the trails of the frame are elongate and narrow, the covers of the PC card kit are far from the mating end and at a rear, free end when the PC card inserts into the electronic equipments. When a bigger outside force acted on the PC card, the free end of the card is easy to be distorted. At this case, the bottom cover will not reliably mounted to the frame and disengage from the top cover. This results in failure of the PC card and degrades the performance of the electronic equipment that uses the card.

Hence, an improved PC card kit is required to overcome the disadvantages of the prior art.

### BRIEF SUMMARY OF THE INVENTION

Accordingly, an object of the present invention is to provide a PC card kit which have improved bonding relationship.

In order to obtain the object, a PC card comprises a pair of shells, a printed circuit board interposed between the shells, an insulative frame supporting the printed circuit board, a top cover, a bottom cover engaging with the top cover, and an enforcement mechanism. The insulative frame includes a pair of longitudinal rails and the top cover is connected with rear ends of the rails. The enforcement mechanism is entirely enclosed within the top cover and the bottom cover when the bottom cover fastened to the top cover. The enforcement mechanism being arranged on front ends of the top and bottom covers and close to the rear ends of the rails in a front to back direction, the enforcement mechanism comprising a protrusion and a recess mating with each other in an up to down direction. The enforcement mechanism is arranged on a joint section of a tabular portion and a extension portion of the PC card kit not only positioning the bottom cover to the extension portion but also increasing the intensity of the PC card kit.c

Other objects, advantages and novel features of the invention will become more apparent from the following detailed description of the present embodiment when taken in conjunction with the accompanying drawings.

### BRIEF DESCRIPTION OF THE DRAWINGS

FIG. 1 is an exploded view of a PC card kit in accordance with the present invention;

FIG. 2 is another exploded view of the PC card kit shown in FIG. 1, while taken from a different aspect;

FIG. 3 is a partly enlarged view taken from the circle in FIG. 2;

FIG. 4 is a perspective view of a bottom cover of the PC card kit; and

FIG. 5 is a perspective view of the PC card kit shown in FIG. 1.

### DETAILED DESCRIPTION OF THE PREFERRED EMBODIMENT

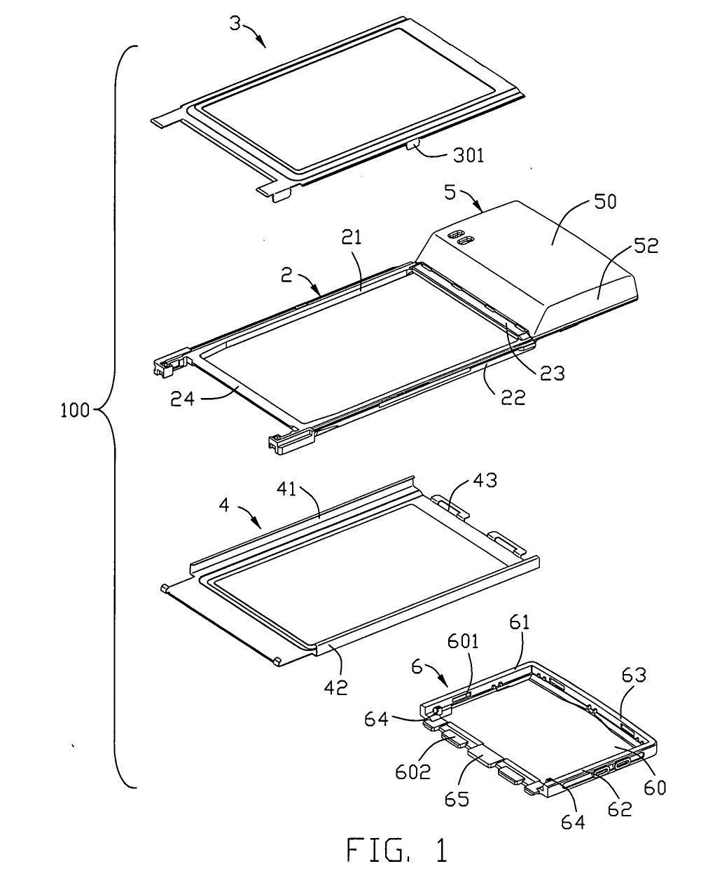

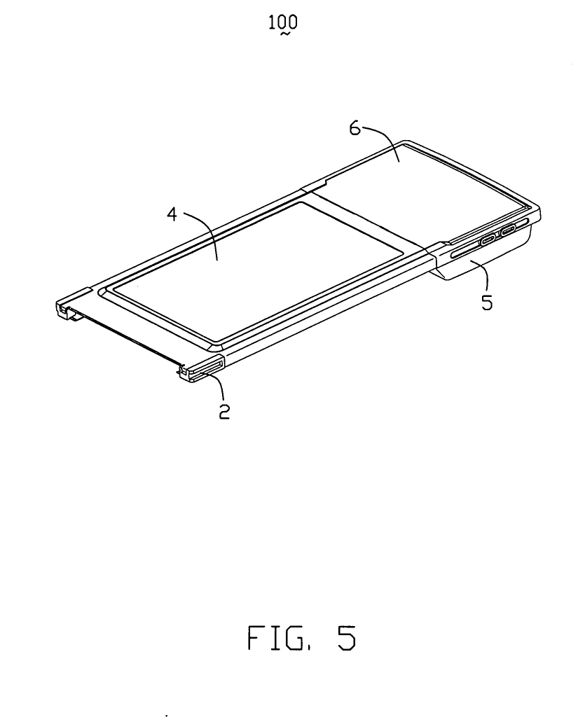

Referring to FIGS. 1, 2 and 5, a PC card 100 in accordance with the present invention for mounting to an electronic device (not shown) includes a pair of metal shells 3, 4, a printed circuit board (not shown) interposed between the shells 3, 4, an insulative frame 2 supporting the printed circuit board, a top cover 5 and a detachable bottom cover 6 mounted to the insulative frame 2. The insulative frame 2 is integrally formed as a rectangular member and includes a pair of longitudinal rails 21, 22, a traverse bar 23, and a connecting bar 24 connected the rails 21, 22 respectively at front and rear ends of the rails 21, 22. A plurality of slits 201 are respectively defined on the rails 21, 22 and the traverse bar 23.

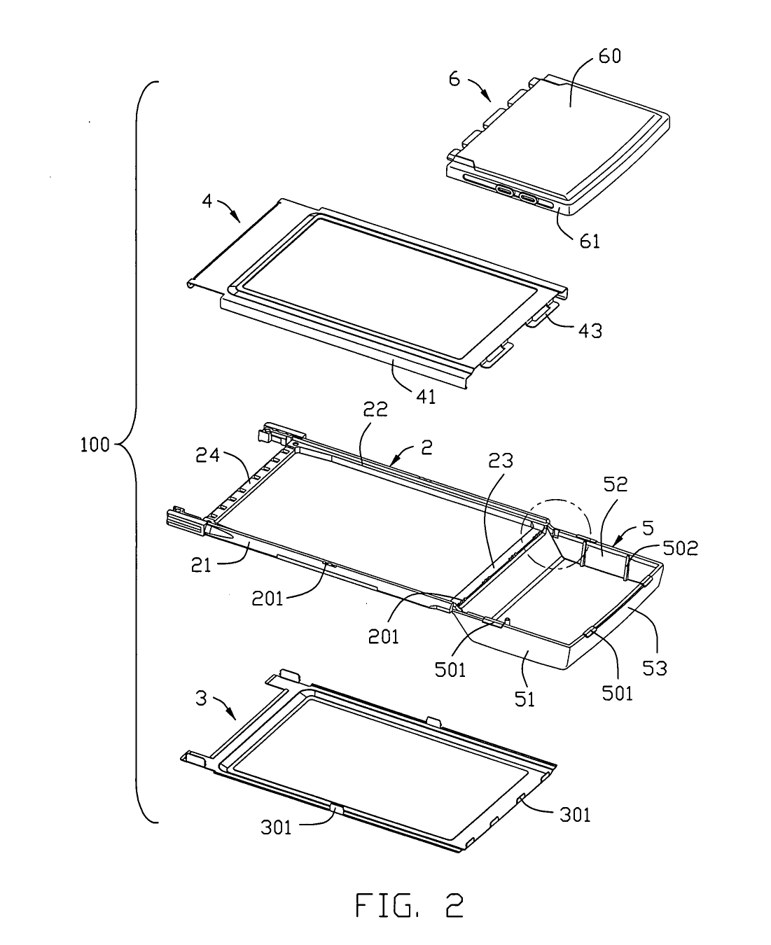

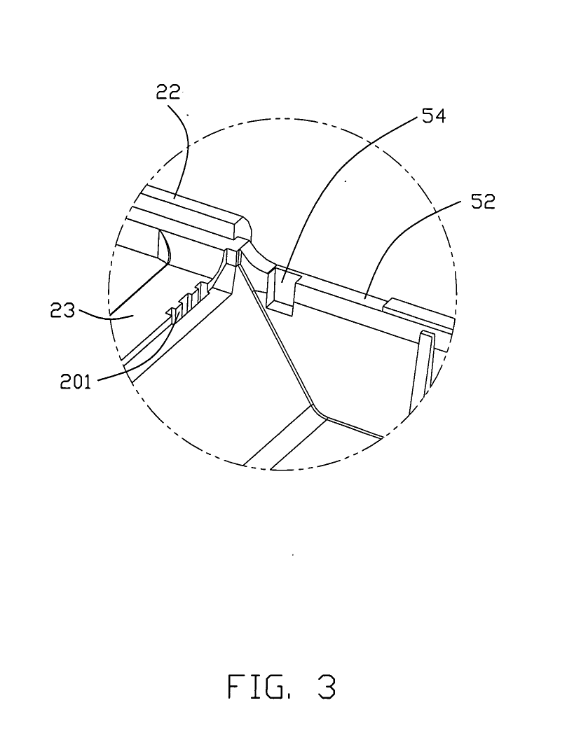

Referring to FIGS. 2 and 3, the fixed top cover or a projecting extension portion extends from the rear ends of the rails 21, 225, which designated number 5. A front end 55 of the top cover 5 is connecting with the frame 2. The top cover 5 has a plate 50, a pair of sidewalls 51, 52 extending upwardly from the plate 50, and a rear wall 53 connecting the sidewalls 51, 52. The sidewalls 51, 52, the rear wall 53, and the plate 50 form a space. A plurality of projections 501 are respectively defined on the sidewalls 51, 52 and the rear wall 53. Each sidewall 51, 52 has a plurality of ribs 502 on the inner face thereof for guiding the insertion of the printed circuit board. A recess 54 is defined on each sidewall 51, 52 of the top cover 5 and close to the rear ends of the rails 21, 22.

Referring to FIGS. 1 and 2, the metal shells are rectangular shape and include a top shell 3 and a bottom shell 4. A plurality of interference tabs 301 extending from opposite sides and rear edge of the top shell 3. The interference tabs 301 are engaging with the slits 201 of the insulative frame 2 for securing the top shell 3 to the insulative frame 2. The bottom shell 4 includes a pair of sidewalls 41, 42 at two opposite side thereof. Two connecting members 43 are formed at a rear end of the bottom shell 4.

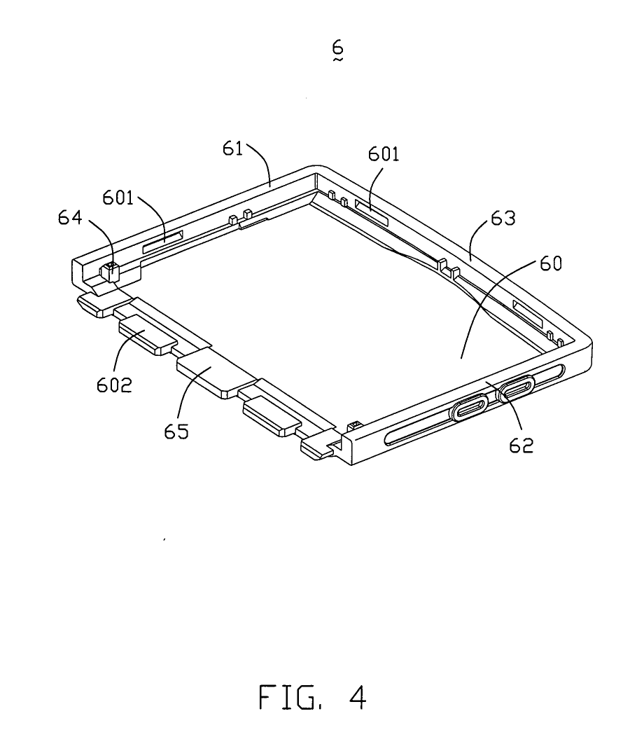

Referring to FIG. 4, the bottom cover 6 includes a plate 60, a pair of sidewalls 61, 62 extending upwardly from the plate 60, and a rear wall 63 connecting the pair of sidewalls 61, 62. A plurality of grooves 601 are defined on the sidewalls 61, 62 and the rear wall 63. The bottom cover 6 has a front end 65 opposite to the rear wall 63. A plurality of connecting members 602 are formed on the front end 65 for engaging with the connecting members 43 of the bottom shell 4. A protrusion 64 is formed on each sidewall 61, 62 and behind the front end 65 in a front to back direction.

In assembly, the bottom shell 4 and the top shell 3 sandwich the insulative frame 2 therebetween to form a tabular portion with a first close space therein. The tabular portion and the top cover 5 constitute a case body wherein the space of the top cover 5 is exposed to an exterior of the case body. The bottom cover 6 is assembly to the top cover 5 thereby forms another close space. The projections 501 and the grooves 601 are mating with each other to form a latch mechanism for securing the bottom cover 6 to the top cover 5. In the same time, the protrusions 64 are received in the recesses 54 in an up to down direction for positioning the bottom cover 6 on the top cover 5. Since the top cover 5 is connected with the rear ends of the insulative frame 2, more importantly, the bottom cover also borders the case body at the joint section of the top cover 5 and the insulative frame 2 in a front to back direction, so the intension of this section is weak and easy to be destructed. The protrusion 64 and the recess 54 form an auxiliary enforcement mechanism for positioning the bottom cover 6 to the top cover 5 when the PC card is working. The protrusion 64 and the recess 54 are entirely enclosed within the top cover 5 and the bottom cover 6. The enforcement mechanism can prevent the displacement between the bottom cover 6 and the top cover 5. The enforcement mechanism also resists the torsion and the inflection brought by an outside force so that the PC card kit has an improved intensity.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

We claim:

1. A PC card comprising:
a pair of shells;
a printed circuit board interposed between the shells;
an insulative frame supporting said printed circuit board, the insulative frame comprising a pair of longitudinal rails;
a first cover connecting with rear ends of the rails,
a second cover mating with the first cover; and
an enforcement mechanism for positioning the said second cover to said first cover, said enforcement mechanism being shaped and arranged so as to be entirely enclosed within said first cover and said second cover when said second cover fastened to the first cover, said enforcement mechanism being arranged on front ends of the first and second covers and close to the rear ends of the rails in a front to back direction, the enforcement mechanism comprising a protrusion and a recess mating with each other in an up to down direction.

2. The PC card as claimed in claim 1, wherein the insulative frame includes a traverse bar connecting the rear ends of the rails and a connecting bar connecting bar connecting front ends of the rails.

3. The PC card as claimed in claim 2, wherein the enforcement mechanism is behind the traverse bar in the front to back direction.

4. The PC card as claimed in claim 1, wherein the second cover comprises a plate, a pair of sidewalls extending upwardly from the plate, and a rear wall connecting the sidewalls, and wherein the protrusion is disposed on the sidewall.

5. The PC card as claimed in claim 4, wherein first cover includes a plate, a pair of sidewalls extending upwardly from the plate, and a back wall connecting the sidewalls, and wherein the recess is disposed on the sidewall.

6. The PC card as claimed in claim 5, further comprising a latch mechanism for fastening the second cover to the first cover, said latch mechanism comprising projections and grooves engaging with the projections, and wherein the projections and grooves being arranged on the sidewalls of the first and second cover respectively.

7. The PC card as claimed in claim 1, wherein the sidewalls of the first cover includes a plurality of ribs for guiding the insertion of the printed circuit board.

8. A PC card kit, comprising:
a case body comprising a tabular portion and an extension portion extending from the tabular portion, the tabular portion defining a close space therein, the extension portion defining a space exposing to an exterior of the case body;
a detachable cover covering the extension portion of the case body; and
an enforcement mechanism being arranged on a joint section of the tabular portion and the extension portion for positioning the said detachable cover to said extension portion, said enforcement mechanism being shaped and arranged so as to be entirely enclosed within said detachable cover and said extension portion when said detachable cover fastened to the case body, the enforcement mechanism comprising a protrusion and a recess mating with each other in an up to down direction.

9. The PC card kit as claimed in claim 8, the tabular portion comprising an insulative frame and a pair of shells for sandwiching the insulative housing therebetween.

10. The PC card kit as claimed in claim 9, wherein the extension portion and the detachable cover defines another close space.

11. The PC card kit as claimed in claim 9, wherein the detachable cover, the detachable cover defines a front edge and a rear edge, and wherein the front edge of the detachable cover is engaging with one of the shells.

12. The PC card kit as claimed in claim 9, further comprising a latch mechanism for latch the extension portion and the detachable cover, said latch mechanism comprising projections and grooves for engaging with the projections.

13. The PC card kit as claimed in claim 8, wherein the enforcement mechanism being defined on the detachable cover and the extension portion.

14. The PC card kit as claimed in claim 8, wherein the enforcement mechanism is arranged on opposite sides of the PC card kit.

15. A PC card comprising:
a shell device;
a printed circuit board interposed between the shells;
an insulative frame supporting said printed circuit board, the insulative frame comprising a pair of longitudinal rails;
a first cover unitarily connecting with rear ends of the rails,
a discrete second cover attached to the first cover; and
an enforcement mechanism for positioning the said second cover to said first cover, said enforcement mechanism being shaped and arranged so as to be entirely enclosed within said first cover and said second cover when said second cover is fastened to the first cover, the enforcement mechanism comprising a protrusion and a recess respectively located on one of said first cover and said second cover, and mated with each other in an up to down direction; wherein
the protrusion extends on an inner surface of a periphery wall of the corresponding one of said first cover and said second cover, and the recess extends in an inner surface of a periphery wall of the corresponding one of said first cover and said second cover.
